(19) United States
(12) Patent Application Publication
(10) Pub. No.: US 2006/0154150 A1
(43) Pub. Date: Jul. 13, 2006

(54) Arrangement for the production of photomasks

(76) Inventors: Thomas Engel, ERFURT (DE); Wolfgang Harnisch, Lehesten (DE); Peter Hoffrogge, Oberkochen (DE); Axel Zibold, Jena (DE)

Correspondence Address: REED SMITH, LLP;ATTN: PATENT RECORDS DEPARTMENT, 599 LEXINGTON AVENUE, 29TH FLOOR, NEW YORK, NY, 10022-7650, US

(21) Appl. No.: 10/520,648

(22) PCT Filed: Jul. 9, 2003
(86) PCT No.: PCT/EP03/07401

§ 371 Date: Sep. 21, 2005

(30) Foreign Application Priority Data
Jul. 9, 2002 (DE) 102 30 755.5

(51) Int. Cl. G03F 1/00

(52) U.S. Cl. 430/4

(57) ABSTRACT

An arrangement and a method for the production of photomasks in which at least one defect control system is connected to at least one repair system by a stationary data connection or online connection, and the defect control system and repair system are connected to one another by data in such a way that the results obtained on one of the systems are immediately available to the other system for further processing. The defect control system conveys detected defects to the repair system via a data connection for data exchange. An AIMS system is advantageously provided as defect control system and an electron beam system is advantageously provided for defect control.

### CROSS-REFERENCE TO RELATED APPLICATIONS

This application claims priority of International Application No. PCT//EP03/07401, filed Jul. 9, 2003, and German Application No. 102 30 755.5, filed Jul. 9, 2002, the complete disclosure of which are hereby incorporated by reference.

### BACKGROUND OF THE INVENTION

### Field of the Invention/Description of the Related Art

An AIMS system (Aerial Image Measurement System) is used for inspecting photomasks in the respective process wavelength (Zeiss MSM 100, MSM 193, AIMS-fab). Different production techniques and processes are used for photomasks and reticles, e.g., in microlithography. For example, there are binary masks, halftone photomasks, as they are called, or straightforward phase masks. Masks of this kind are fabricated on a substrate; one of the surfaces of the substrate or a layer applied to the substrate is structured during fabrication. During the production of masks, particularly during coating and structuring, and during handling of the masks, defects occur on the mask which are analyzed by the AIMS system.

An electron beam crossbeam system, for example, which is suitable for repairing transparent locations on the mask, e.g., by chrome deposition (LEO Photo Mask Repair Tool) is provided for repairing defects of the type mentioned above. Further, the state of e-beam based repair systems (cross beam) is described in U.S. Pat. No. 5,148,024 and U.S. Pat. No. 5,055,696. Further, systems for material removal (repair systems) are known. Laser repair systems or AFM systems (RAVE) are commercially available for this purpose.

### SUMMARY OF THE INVENTION

According to the invention, an integration of the measurement system and repair system is carried out using a database and advantageously also in a common sample chamber. Further, the invention proposes measuring and repairing the sample in the same place and possibly at the same time as an in-situ control.

Examples of a measurement system include an AIMS system, a microscope, an AFM (Atomic Force Microscope), a FIB system (Focussed Ion Beam) or an electron beam microscope. However, because of the other imaging characteristics of light-optical to particle-optical systems or nearfield systems, a plurality of supplementing systems can also be used as complimentary monitoring or control systems.

Repair systems can be:

systems for material removal;

systems for material deposition;

or a combination of these systems as deposition and ablation systems for repair.

These two repair systems can possibly be integrated in one system. Embodiment forms are shown in FIGS. 1 to 6.

### BRIEF DESCRIPTION OF THE DRAWINGS

In accordance with the drawings:

FIG. 1a schematically shows an AIMS system and a repair system which can function as an electron beam-based repair tool or a repair system for material removal;

FIG. 1b shows, in addition to that shown in FIG. 1a, a central control unit which acts as a master system in accordance with the invention;

FIG. 1c schematically shows how individual control units can be accommodated in the central control unit;

FIGS. 2a, 2b and 2c further schematically show the measurement system and the repair system being accommodated in a common measurement chamber;

FIGS. 3a, 3b and 3c schematically show an arrangement of a repair system in a measurement system in accordance with the invention;

FIGS. 4a and 4b schematically show alternative arrangements of the repair system of the present invention;

FIGS. 5a-d schematically show different variants of a device for ablating chrome by means of a laser that is connected to the common control unit in accordance with the invention; and

FIGS. 6a-e schematically show integration of a unit in the common measurement chamber so that optimal conditions can be adjusted for the repair units with parallel measurement.

### DESCRIPTION OF THE PREFERRED EMBODIMENTS

Possibilities for Integrating the Systems Using a Database:

a) Connection Between the Control Systems of the Two Individual Systems.

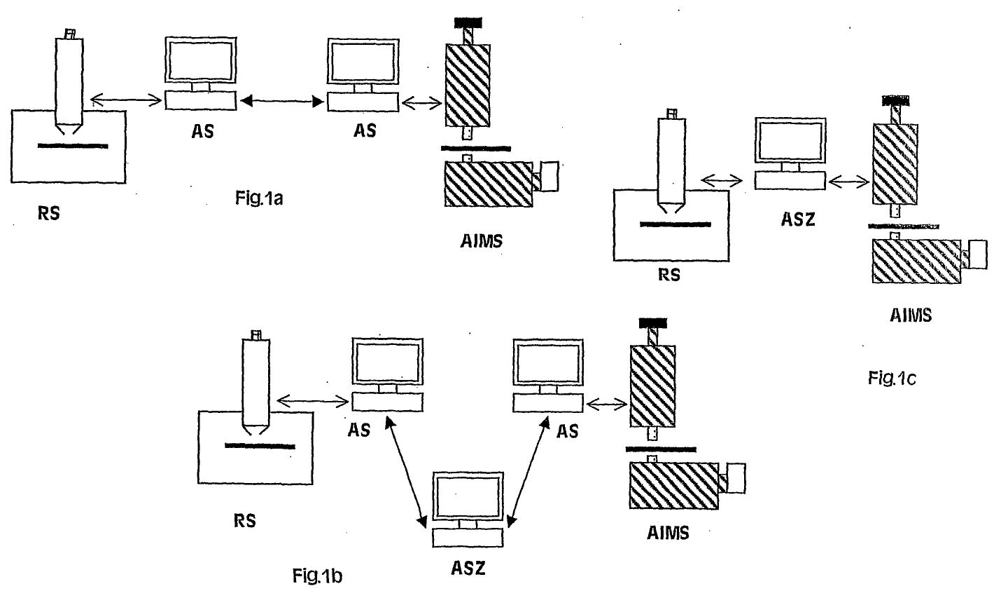

FIG. 1a shows schematically an AIMS system and a repair system RS which can be an electron beam-based repair tool or a repair system for material removal. The respective control systems AS are shown schematically. These control systems are advantageously connected for data exchange via interfaces. In this way, the repair of the masks can be carried out based on, and immediately following, analysis by the AIMS system and a new analysis and new repair are also possible.

b) Connection of the Systems by a Master System that can be Expanded as an Expert System.

FIG. 1b shows, in addition, a central control unit ASZ which acts as a master system and coordinates the measurement process and repair process. It can also be adaptive, e.g., with a database system for output of repair suggestions for detected defects that are already known and prestored. In addition, sample handling is controlled, for example, by means of a common platform (not shown) on which the masks are displaced from measurement system to repair system. The individual control units can also be unified and accommodated in the central control unit ASZ as is shown in FIG. 1c.

Integration of the Systems in a Measurement Chamber:

(Different Samples can Also be Processed in Parallel in the Two Systems)

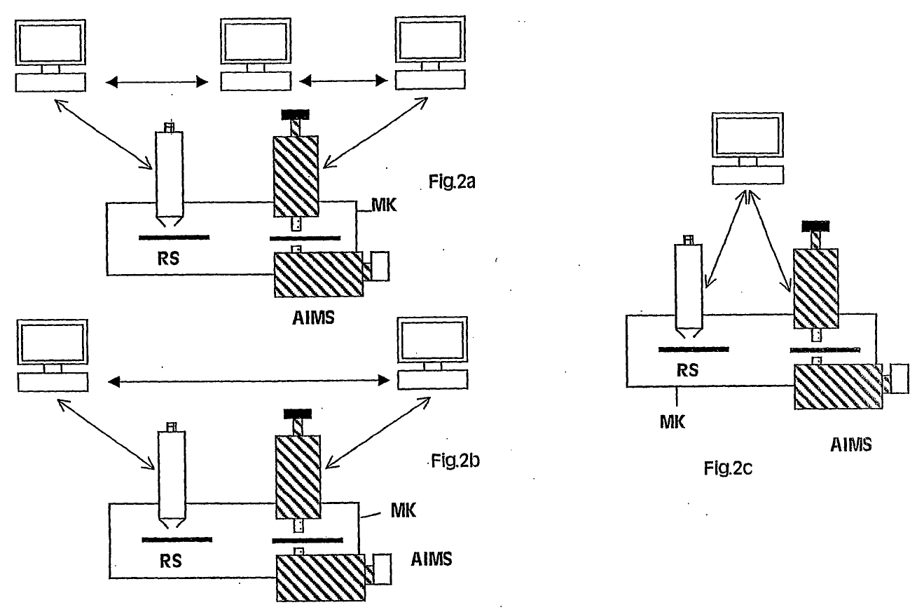

In FIGS. 2a-c, the measurement system and the repair system are accommodated in a common measurement chamber MK. The data exchange is carried out as shown in FIG. 1. The advantage consists in that the conditions for the repair system (vacuum) can already exist in that the measurement chamber in its entirety contains a vacuum so that it is possible to change very quickly from the measuring process to the repair process.

As in FIG. 1c, a central control unit ASZ is provided in FIGS. 2a, c.

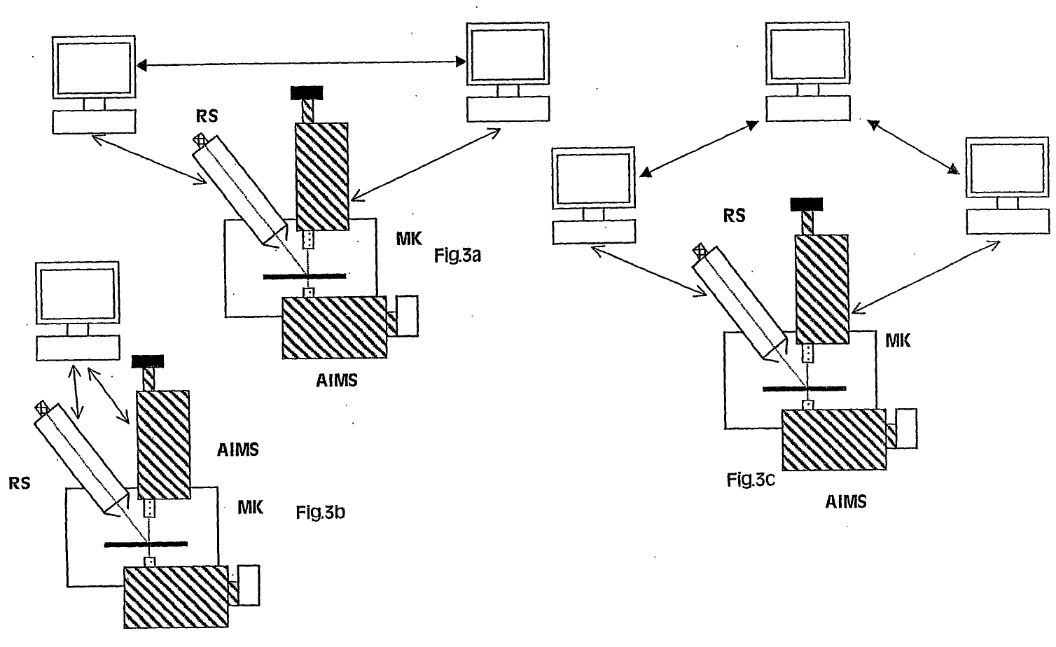

FIGS. 3a-c show an arrangement of a (diagonally arranged) repair system in a measurement system.

The measurement axis and the repair axis intersect in the object or there is at least an overlapping of the visual field of the measurement system with the working area of the repair system.

In this case, a measurement can be carried out during the repair so that the repair can be oriented in accordance with measurements.

The Figures mentioned above show AIMS and electron microscopes by way of example. However, any repair systems for a corresponding combination can be used according to the invention. By way of expansion, the following case is also possible:

access of the repair system from the structure side of the mask for application or removal of material;

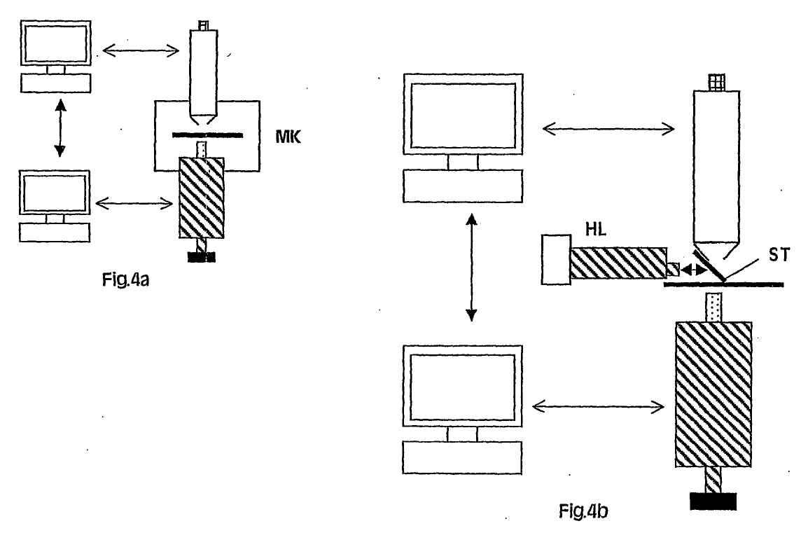

access of the microscope (AIMS) from the other side of the mask for optical measurement using reflection. This is shown in FIG. 4a.

In addition or alternatively, transmitted illumination is carried out in FIG. 4b in the direction of the measurement system by means of a beam splitter ST and a switchable auxiliary illumination HL for measuring in transmission so that the axes or work areas of the repair system and AIMS overlap. In this case, AIMS inspection of the mask is carried out in the reverse direction through the mask, that is, the imaging takes place through the glass substrate. This advantageously requires at least a matching spherical adaptation of the imaging system because of the thickness of the mask substrate in the imaging path through correspondingly adapted system optics and/or objectives.

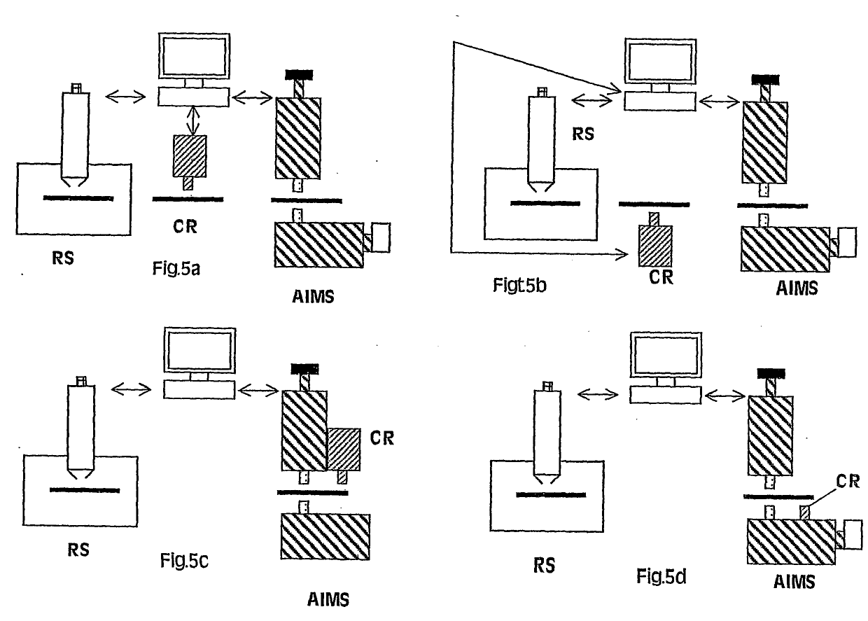

Further, FIGS. 5a-d show different variants of a device CR for ablating chrome by means of a laser that is connected to the common control unit ASZ.

The drawing shows a separate system for removal of chrome that is conceived as a component of the total system. This system for chrome removal can be arranged as a standalone system (5a) and can pursue all possible repair mechanisms since it is possible to directly access the chrome layer for chrome removal. A repair tool could also be an AFM or an ablating laser.

This applies in an analogous manner to FIG. 5c since the above arrangement is also selected in this case. Combination by spatial connection and integration with the AIMS system is shown only by way of example. This can be advantageous because indirect prepositioning, if required, is possible by means of the visual inspection.

In the other two parts of the drawing, 5b, 5d, the arrangement of the repair system from below is selected. In this case, only repair processes which function through the mask are possible. This can be, for example, ablation with focused laser beam because the layer on the mask typically exhibits a higher absorption and lower destruction threshold and is accordingly ablated sooner without the mask being destroyed. The last part of the illustration shows the integration in the transmitted light unit because, e.g., the unattenuated laser beam is available in this case.

Generally, auxiliary observation systems are possible for positioning and/or precision positioning.

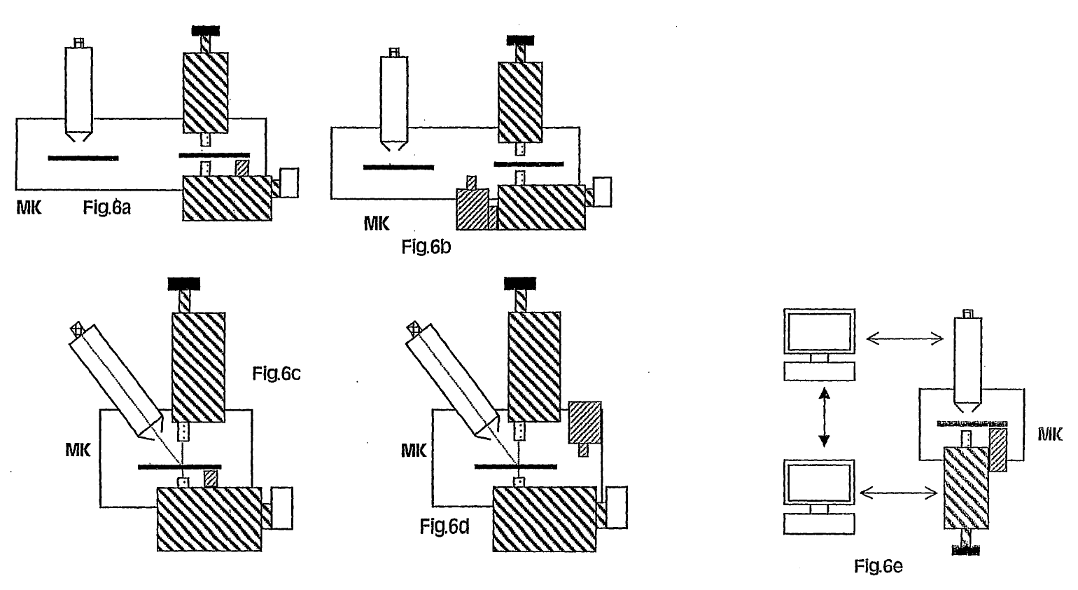

FIGS. 6a-e show the unit CR integrated in the common measurement chamber MK so that optimal conditions can be adjusted for the repair units with parallel measurement.

At 157 nm/EUV, for example, it is required that the AIMS be arranged in a protective gas environment or in a vacuum. Since the electron microscope must also work under vacuum, integration in a common chamber is possible in principle. At longer working wavelengths, it is also possible to carry out the AIMS system under vacuum so that it can be integrated in a measurement chamber with the repair system. In case of greater contamination by the repair methods, it may be necessary to separate the two systems by means of airlocks or partitioning to provide the vacuum so that no mutual contamination can take place. This is not shown in the drawing. However, by creating common work conditions for electron beam ablation and AIMS, i.e., without using airlocks or partitioning, the advantage is achieved that no airlocks need to be used for the masks from one system to the other. Accordingly, this form of integration boosts the productivity of the system. The arrangements of the unit CR in FIGS. 6a, b, e correspond to those shown in FIG. 5. FIGS. 6c and d show the construction, illustrated in FIG. 3, with an intersection of the measurement axis and repair axis.

Operating the AIMS system by itself under vacuum is likewise advantageous, particularly by excluding optical interference due to the atmosphere.

An AIMS system in generalized form would be a system working with the imaging medium with which the model or photomask is also used in the production process. This can be light in the Vis, UV, DUV or EUV range, electrons, ions, or x-ray.

While the foregoing description and drawings represent the present invention, it will be obvious to those skilled in the art that various changes may be made therein without departing from the true spirit and scope of the present invention.

What is claimed is:

1-25. (canceled)

26. An arrangement for the production of photomasks, comprising:
at least one defect control system; and
at least one repair system or measurement;
said at least one defect control system being connected to said at least one repair system or measurement by a continuous data connection or online connection.

27. The arrangement according to claim 26, wherein a direct data exchange or an indirect exchange is carried out by means of a central device.

28. The arrangement according to claim 26, wherein at least one defect control system and at least one repair system are connected to one another by data in such a way that the results obtained on one of the systems are immediately available to the other system for further processing.

29. The arrangement according to claim 26, wherein an AIMS system is provided as defect control system.

30. The arrangement according to claim 26, wherein an electron beam system is provided for defect control.

31. The arrangement according to claim 26, wherein an electron beam-based deposition system is provided as repair system.

32. The arrangement according to claim 26, wherein a laser ablation system is provided as repair system.

33. The arrangement according to claim 26, wherein an AFM (Atomic Force Microscope) is provided as a measurement system and/or repair system.

34. The arrangement according to claim 26, wherein a FIB (Focused Ion Beam) system is provided as a measurement system and/or repair system.

35. The arrangement according to claim 26, wherein a connection for data exchange is carried out by the control units of the system.

36. The arrangement according to claim 26, wherein a common co control unit is provided for coordinating between measurement and repair.

37. The arrangement according to claim 26, wherein the defect control system and repair system are arranged in a common measurement chamber.

38. The arrangement according to claim 37, wherein a vacuum is generated or a protective atmosphere is provided in the common chamber.

39. The arrangement according to claim 26, wherein a transport system is provided between the defect control system and repair system.

40. The arrangement according to claim 26, wherein a common platform with adjusting devices is provided for the defect control system and repair system.

41. The arrangement according to claim 26, wherein the direction of the measurement axis and repair axis intersect at a common point and/or the working areas of the measurement system and repair system overlap.

42. The arrangement according to claim 41, wherein the direction of the repair axis is inclined relative to the measurement axis of the AIMS system.

43. The arrangement according to claim 26, wherein the measurement system is arranged on the side of the mask remote of the structure side and the repair system is arranged on the structure side.

44. The arrangement according to claim 43, wherein the measurement system works in transmission mode.

45. The arrangement according to claim 43, wherein the measurement system detects the radiation transmitted through the mask, wherein additional illumination is coupled in on the side remote of the measurement system, preferably by means of a beam splitter or deflecting element.

46. The arrangement, particularly according to claim 26, wherein an AIMS system is operated under vacuum conditions.

47. A method for the production of photomasks, particularly with an arrangement according to claim 26, comprising the steps of having a defect control system convey detected defects via a data connection for data exchange to at least one repair system that controls the repair process based on the determined defects.

48. The method according to claim 47, wherein measurement and repair are carried out simultaneously.

49. The method according to claim 47, with a sequence of repair and measurement that is carried out repeatedly.

50. The method according to claim 45, wherein the illumination light of the measurement system is used for removal of material.
